(19) United States
(12) Patent Application Publication
(10) Pub. No.: US 2008/0316062 A1
(43) Pub. Date: Dec. 25, 2008

(54) METHOD FOR INPUTTING KEYBOARD COMMANDS

(76) Inventors: Chien-Tsung CHEN, Sijhih City (TW); Yen-Liang Kuan, Sijhih City (TW)

Correspondence Address: Muncy, Geissler, Olds & Lowe, PLLC, P.O. BOX 1364, FAIRFAX, VA, 22038-1364, US

(21) Appl. No.: 12/051,418

(22) Filed: Mar. 19, 2008

(30) Foreign Application Priority Data
Jun. 22, 2007 (TW) 96122603

(51) Int. Cl. H03M 11/00; H03K 17/94

(52) U.S. Cl. 341/22

(57) ABSTRACT

A method for negotiating keyboard commands between a computer and an external keyboard is provided. The computer and the external keyboard have respective NL (number lock) status. When the external keyboard is pressed, the external keyboard act as the following mechanics. When NL status of the computer is “Off” and NL status of the external keyboard is “On”, and a time internal between adjacent serially-pressed numeric keys of the external keyboard is less than a predetermined time period, a key code of NL on the external keyboard is firstly sent to alter NL status of the computer from “Off” to “On”, key codes of pressed numeric keys of the external keyboard are secondly sent to the computer, and the key code of NL on the external keyboard is finally sent to alter NL status of the computer from “On” to “Off”.

### RELATED APPLICATIONS

This application claims priority to Taiwan Application Serial Number 96122603, filed Jun. 22, 2007, which is herein incorporated by reference.

### BACKGROUND

1. Field of Invention

The present invention relates to a keyboard command inputting method. More particularly, the present invention relates to a method for negotiating keyboard commands between a computer and an external keyboard.

2. Description of Related Art

FIG. 1 illustrates a conventional keyboard of a desktop computer. The keyboard 100 includes an area 102 of alphanumeric keys, a functional key area 104, a numeric key area 106 and a directional key area 108. When number lock (NL) status of the numeric key area 106 is “On”, the numeric key area 106 being pressed outputs numbers on the display screen. When number lock (NL) status of the numeric key area 106 is “Off”, the numeric key area 106 being pressed performs corresponding function (such as directional control).

However, a conventional keyboard 150 (as illustrated in FIG. 2) on a notebook computer has a different layout due a limited area. Besides a general numeric key area, an extra numeric key area 154 is designed in an alphabetic key area 156. The keyboard 150 also has a number lock (NL) key to switch the numeric key area 154 selectively output numeric key codes or alphabetic key codes.

It is inconvenient to switch NL status of the keyboard 150, however, some keyboard vender thus provides a small external keyboard 170 for commonly used with a main keyboard of a computer system. The external keyboard 170 may be used instead of the numeric key area 106 on the keyboard 100 or the numeric key area 154 of the keyboard 150.

When the external keyboard 170 (as illustrated in FIG. 3) is commonly used with the keyboard 100 (as illustrated in FIG. 1) or the keyboard 150 (as illustrated in FIG. 2), NL status for each keyboard may be different from each other. When two commonly used keyboards, i.e. the external keyboard 170 and the keyboard 150, are inconsistent in NL status, keyboard command inputting can be confused.

### SUMMARY

It is therefore an objective of the present invention to provide a method for negotiating keyboard commands between a computer and an external keyboard

In accordance with the foregoing and other objectives of the present invention, a method for negotiating keyboard commands between a computer and an external keyboard is provided. The computer and the external keyboard have respective NL (number lock) status. When the external keyboard is pressed, the external keyboard act as the following mechanics. When NL status of the computer is “Off” and NL status of the external keyboard is “On”, and a time internal between adjacent serially-pressed numeric keys of the external keyboard is less than a predetermined time period, a key code of NL on the external keyboard is firstly sent to alter NL status of the computer from “Off” to “On”, key codes of pressed numeric keys of the external keyboard are secondly sent to the computer, and the key code of NL on the external keyboard is finally sent to alter NL status of the computer from “On” to “Off”.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a conventional keyboard of a desktop computer;

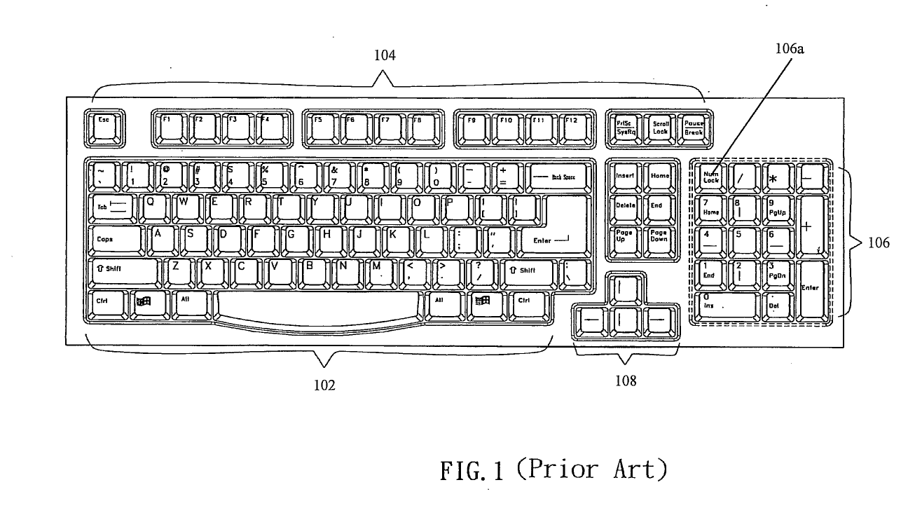

FIG. 2 illustrates a conventional keyboard of a notebook computer;

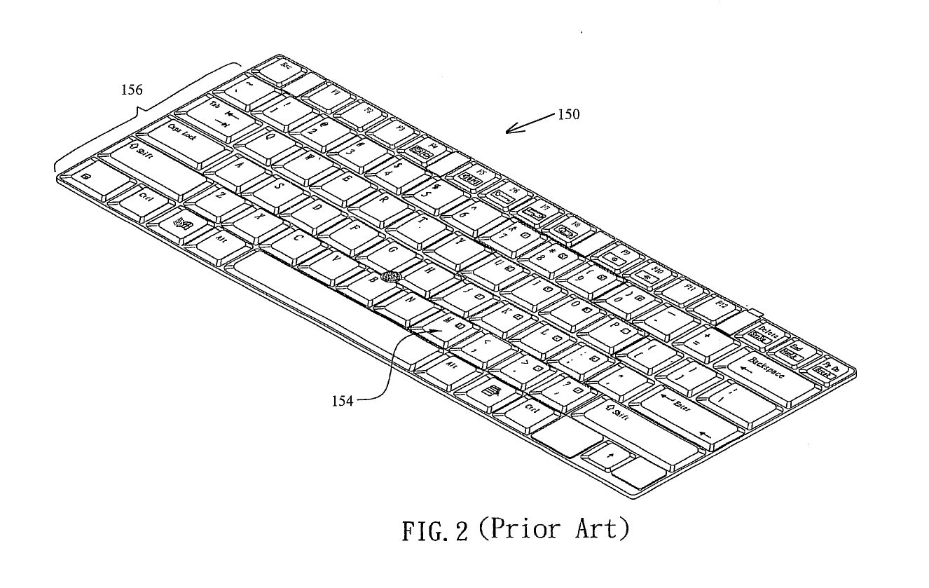

FIG. 3 illustrates a conventional external keyboard; and

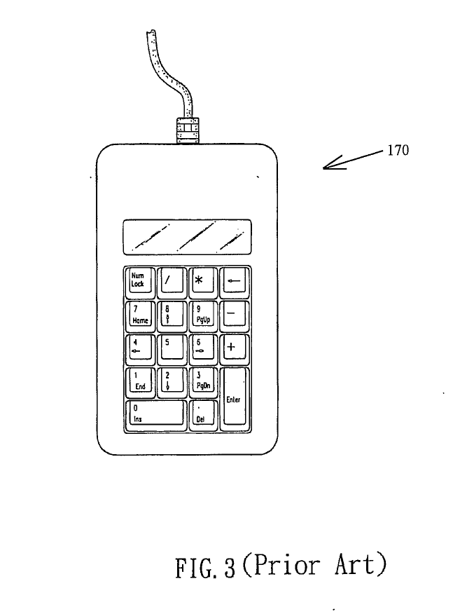

FIG. 4 illustrates a notebook computer and an external keyboard according to an embodiment described herein.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

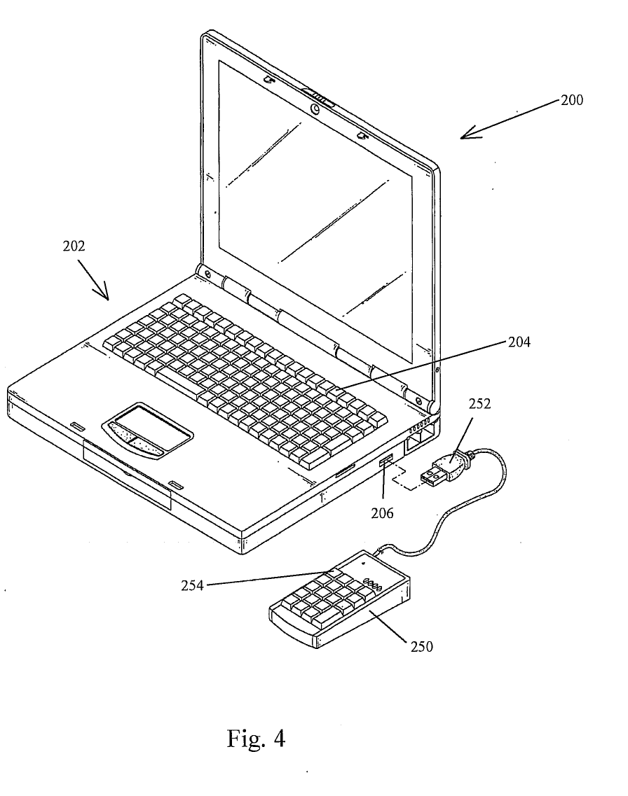

FIG. 4 illustrates a notebook computer and an external keyboard according to an embodiment described herein. When the notebook computer 200 and the external keyboard 250 are commonly used, i.e. a connector 252 of the external keyboard 250 is electrically connected with a corresponding connection port 206 of the notebook computer 200, Number Lock (hereafter NL) status, i.e. shown by a NL LED light, of the notebook computer 200 and Number Lock (hereafter NL) status, i.e. shown by a NL LED light, of the external keyboard 250 would have 4 sets of status (as shown in table 1). Main keyboard 202 on the notebook computer 200 has a NL 204 to switch the NL status between “On” and “Off”. The external keyboard 250 also has a NL 254 to switch the NL status between “On” and “Off”.

TABLE 1

| | NL status | |
|---|---|---|
| | of External | |
| NL status of | Keyboard | When external keyboard 250 is pressed, what external |
| computer 200 | 250 | keyboard 250 act: |
| Off | Off | Sending key codes of pressed keys on external keyboard |
| | | 250 to computer 200 |
| Off | On | (1) Sending key code of NL on external keyboard 250 to |
| | | alter NL status of computer 200; (2) Sending key codes |
| | | of pressed numeric keys on external keyboard 250 to |
| | | computer 200; (3) When external keyboard 250 has not |
| | | pressed for a predetermined period, sending key code of |
| | | NL on external keyboard 250 to alter NL status of |
| | | computer 200 |
| On | Off | Sending key codes of computer 200, which is |
| | | corresponding to pressed keys on external keyboard 250 |
| | | to computer 200 |
| On | On | Sending key codes of pressed keys on external keyboard |
| | | 250 to computer 200 |

Table 1 shows operation mechanics for 4 sets of status when users press the external keyboard 250, which is commonly used with the notebook computer 200.

When NL status of the computer 200 is “Off” (i.e. NL LED turn off) and NL status of the external keyboard 250 is “Off” (i.e. NL LED turn off), the external keyboard 250 sends key codes of pressed keys to the computer 200.

When NL status of the computer 200 is “Off” (i.e. NL LED turn off) and NL status of the external keyboard 250 is “On” (i.e. NL LED turn on), the external keyboard 250 performs the following sequence: (1) sending a key code of NL on the external keyboard 250 to alter a NL status of the computer 200, i.e. to switch NL status of the computer 200 from “off” to “on”; (2) sending key codes of pressed numeric keys to the computer 200; (3) when no keys of the external keyboard 250 has not been pressed for a predetermined time period, sending a key code of NL on external keyboard 250 to alter the NL status of computer 200, i.e. to switch NL status of the computer 200 from “on” to “off”. That is, in step (2), the external keyboard 250 would not send a key code of NL on external keyboard 250 to alter the NL status of the computer 200 when a time internal between adjacent serially-pressed keys is less than a predetermined time period (such as 0.3˜0.5 sec). The step (3) is designed for the particular case of quickly serially pressing keys on the external keyboard 250. When the external keyboard 250 is serially pressed quickly, i.e. a time internal between adjacent serially-pressed keys is less than 0.3˜0.5 sec, the key code of NL on the external keyboard 250 in step (3) is postponed to send. Once no keys of the external keyboard 250 has not been pressed for a predetermined time period, the external keyboard 250 would send a key code of NL on external keyboard 250 to alter the NL status of the computer 200. Step (3) is to resolve the delaying issue of key codes when the external keyboard 250 is serially pressed quickly.

When NL status of the computer 200 is “On” (i.e. NL LED turn on) and NL status of the external keyboard 250 is “Off” (i.e. NL LED turn off), the external keyboard 250 sends key codes of computer 200, which is corresponding to pressed keys on external keyboard 250, to the computer 200.

When NL status of the computer 200 is “On” (i.e. NL LED turn on) and NL status of the external keyboard 250 is “On” (i.e. NL LED turn on), the external keyboard 250 sends key codes of pressed keys to the computer 200.

Referring to the following Table 2, which shows another operation mechanics for 4 sets of status when users press the external keyboard 250, which is commonly used with the notebook computer 200.

TABLE 2

| | NL status | |
|---|---|---|
| | of External | |
| NL status of | Keyboard | When external keyboard 250 is pressed, what external |
| computer 200 | 250 | keyboard 250 act: |
| Off | Off | Sending key codes of pressed keys on external keyboard |
| | | 250 to computer 200 |
| Off | On | (1) Sending key code of NL on external keyboard 250 to |
| | | alter NL status of computer 200; (2) Sending key codes |
| | | of pressed numeric keys on external keyboard 250 to |
| | | computer 200; (3) When external keyboard 250 has not |
| | | pressed for a predetermined period, sending key code of |
| | | NL on external keyboard 250 to alter NL status of |
| | | computer 200 |
| On | Off | Temporary status; sending key code of NL on external |
| | | keyboard 250 to alter NL status of computer 200 |
| On | On | Sending key codes of pressed keys on external keyboard |
| | | 250 to computer 200 |

Table 2 has only one operation mechanics (when NL status of the computer 200 is “On” and NL status of the external keyboard 250 is “Off”), which is different from operation mechanics in Table 1.

When NL status of the computer 200 is “On” (i.e. NL LED turn on) and NL status of the external keyboard 250 is “Off” (i.e. NL LED turn off), the external keyboard 250 send a key code of NL on the external keyboard 250 to alter NL status of the computer 200, i.e. switch NL status of the computer 200 from “on” to “off”. This set of NL status is a temporary status. Thus, Table 2 actually has three sets of NL status.

Referring to the following Table 3, which shows another operation mechanics for 4 sets of status when users press the external keyboard 250, which is commonly used with the notebook computer 200.

TABLE 3

| | NL status | |
|---|---|---|
| | of External | |
| NL status of | Keyboard | When external keyboard 250 is pressed, what external |
| computer 200 | 250 | keyboard 250 act: |
| Off | Off | Sending key codes of pressed keys on external keyboard |
| | | 250 to computer 200 |
| Off | On | (1) Sending key code of NL on external keyboard 250 to |
| | | alter NL status of computer 200; (2) Sending key codes |
| | | of pressed numeric keys on external keyboard 250 to |
| | | computer 200; (3) When external keyboard 250 has not |
| | | pressed for a predetermined period, sending key code of |
| | | NL on external keyboard 250 to alter NL status of |
| | | computer 200 |
| On | Off | Temporary status; sending key code of NL on external |
| | | keyboard 250 to alter NL status of computer 200 |
| On | On | Temporary status; sending key code of NL on external |
| | | keyboard 250 to alter NL status of computer 200 |

Table 3 has only one operation mechanics (when NL status of the computer 200 is “On” and NL status of the external keyboard 250 is “On”), which is different from operation mechanics in Table 2.

When NL status of the computer 200 is “On” (i.e. NL LED turn on) and NL status of the external keyboard 250 is “On” (i.e. NL LED turn on), the external keyboard 250 send a key code of NL on the external keyboard 250 to alter NL status of the computer 200, i.e. switch NL status of the computer 200 from “on” to “off”. This set of NL status is a temporary status. Thus, Table 3 actually has two sets of NL status.

Referring to the following Table 4, which shows another operation mechanics for 4 sets of status when users press the external keyboard 250, which is commonly used with the notebook computer 200.

TABLE 4

| | NL status | |
|---|---|---|
| | of External | |
| NL status of | Keyboard | When external keyboard 250 is pressed, what external |
| computer 200 | 250 | keyboard 250 act: |
| Off | Off | Sending key codes of pressed keys on external keyboard |
| | | 250 to computer 200 |
| Off | On | (1) Sending key code of NL on external keyboard 250 to |
| | | alter NL status of computer 200; (2) Sending key code of |
| | | single pressed numeric key on external keyboard 250 to |
| | | computer 200; (3) sending key code of NL on external |
| | | keyboard 250 to alter NL status of computer 200 |
| On | Off | Temporary status; sending key code of NL on external |
| | | keyboard 250 to alter NL status of computer 200 |
| On | On | Temporary status; sending key code of NL on external |
| | | keyboard 250 to alter NL status of computer 200 |

Table 4 has only one operation mechanics (when NL status of the computer 200 is “Off” and NL status of the external keyboard 250 is “On”), which is different from operation mechanics in Table 3.

When NL status of the computer 200 is “Off” (i.e. NL LED turn off) and NL status of the external keyboard 250 is “On” (i.e. NL LED turn on), the external keyboard 250 performs the following sequence: (1) sending a key code of NL on the external keyboard 250 to alter a NL status of the computer 200, i.e. to switch NL status of the computer 200 from “off” to “on”; (2) sending key code of single pressed key to the computer 200; (3) sending a key code of NL on external keyboard 250 to alter the NL status of computer 200, i.e. to switch NL status of the computer 200 from “on” to “off”. Table 4 actually has two sets of NL status. NL status “On” of the computer 200 is a temporary status.

Referring to the following Table 5, which shows another operation mechanics for 4 sets of status when users press the external keyboard 250, which is commonly used with the notebook computer 200.

TABLE 5

| | NL status | |
|---|---|---|
| | of External | |
| NL status of | Keyboard | When external keyboard 250 is pressed, what external |
| computer 200 | 250 | keyboard 250 act: |
| Off | Off | Sending key codes of pressed keys on external keyboard |
| | | 250 to computer 200 |
| Off | On | (1) Sending key code of NL on external keyboard 250 to |
| On | Off | alter NL status of computer 200; (2) Sending key codes |
| | | of pressed numeric keys on external keyboard 250 to |
| | | computer 200; (3) When external keyboard 250 has not |
| | | pressed for a predetermined period, sending key code of |
| | | NL on external keyboard 250 to alter NL status of |
| | | computer 200 |
| On | On | Sending key codes of pressed keys on external keyboard |
| | | 250 to computer 200 |

Table 5 has only one operation mechanics (when NL status of the computer 200 is “On” and NL status of the external keyboard 250 is “Off”), which is different from operation mechanics in Table 1 or Table 2.

When NL status of the computer 200 is “On” (i.e. NL LED turn on) and NL status of the external keyboard 250 is “Off” (i.e. NL LED turn off), the external keyboard 250 performs the following sequence: (1) sending a key code of NL on the external keyboard 250 to alter a NL status of the computer 200, i.e. to switch NL status of the computer 200 from “on” to “off”; (2) sending key codes of pressed numeric keys to the computer 200; (3) when no keys of the external keyboard 250 has not been pressed for a predetermined time period, sending a key code of NL on external keyboard 250 to alter the NL status of computer 200, i.e. to switch NL status of the computer 200 from “off” to “on”. That is, in step (2), the external keyboard 250 would not send a key code of NL on external keyboard 250 to alter the NL status of the computer 200 when a time internal between adjacent serially-pressed keys is less than a predetermined time period (such as 0.3˜0.5 sec). The step (3) is designed for the particular case of quickly serially pressing keys on the external keyboard 250. When the external keyboard 250 is serially pressed quickly, i.e. a time internal between adjacent serially-pressed keys is less than 0.3˜0.5 sec, the key code of NL on the external keyboard 250 in step (3) is postponed to send. Once no keys of the external keyboard 250 has not been pressed for a predetermined time period, the external keyboard 250 would send a key code of NL on external keyboard 250 to alter the NL status of the computer 200. Step (3) is to resolve the delaying issue of key codes when the external keyboard 250 is serially pressed quickly.

In discussed embodiments, the keyboard operation mechanics as described herein can overcome key code delaying or missing of when the external keyboard is serially pressed quickly. Besides, the keyboard operation mechanics can also compatibility issue of the external keyboard while using the external keyboard to play a computer game.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for negotiating keyboard commands between a computer and an external keyboard, the computer and the external keyboard has respective NL (number lock) status, when the external keyboard is pressed, the method comprising:
when NL status of the computer is “Off” and NL status of the external keyboard is “On”, and a time internal between adjacent serially-pressed numeric keys of the external keyboard is less than a predetermined time period,
firstly sending a key code of NL on the external keyboard to alter NL status of the computer from “Off” to “On”,
secondly sending key codes of pressed numeric keys of the external keyboard to the computer, and
finally sending the key code of NL on the external keyboard to alter NL status of the computer from “On” to “Off”.

2. The method of claim 1, wherein the predetermined time period is 0.3˜0.5 sec.

3. The method of claim 2, further comprising:
when NL status of the computer is “Off” and NL status of the external keyboard is “Off”, sending key codes of pressed keys of the external keyboard to the computer.

4. The method of claim 3, further comprising:
when NL status of the computer is “On” and NL status of the external keyboard is “Off”, sending a key codes of the computer, which are corresponding to pressed keys on the external keyboard, to the computer.

5. The method of claim 4, further comprising:
when NL status of the computer is “On” and NL status of the external keyboard is “On”, sending key codes of pressed keys of the external keyboard to the computer.

6. The method of claim 3, further comprising:
when NL status of the computer is “On” and NL status of the external keyboard is “Off”, sending the key code of NL on the external keyboard to alter NL status of the computer from “On” to “Off”.

7. The method of claim 6, further comprising:
when NL status of the computer is “On” and NL status of the external keyboard is “On”, sending key codes of pressed keys of the external keyboard to the computer.

8. The method of claim 6, further comprising:
when NL status of the computer is “On” and NL status of the external keyboard is “On”, sending the key code of NL on the external keyboard to alter NL status of the computer from “On” to “Off”.

9. A method for negotiating keyboard commands between a computer and an external keyboard, the computer and the external keyboard has respective NL (number lock) status, when the external keyboard is pressed, the method comprising:
when NL status of the computer is “On” and NL status of the external keyboard is “Off”, sending a key code of NL on the external keyboard to alter NL status of the computer from “On” to “Off”; and
when NL status of the computer is “On” and NL status of the external keyboard is “On”, sending the key code of NL on the external keyboard to alter NL status of the computer from “On” to “Off”.

10. The method of claim 9, further comprising:
when NL status of the computer is “Off” and NL status of the external keyboard is “Off”, sending key codes of pressed keys of the external keyboard to the computer.

11. The method of claim 10, further comprising:
when NL status of the computer is “Off” and NL status of the external keyboard is “On”,
firstly sending a key code of NL on the external keyboard to alter NL status of the computer from “Off” to “On”,
secondly sending a key code of single pressed numeric key of the external keyboard to the computer, and
finally sending the key code of NL on the external keyboard to alter NL status of the computer from “On” to “Off”.

12. A method for negotiating keyboard commands between a computer and an external keyboard, the computer and the external keyboard has respective NL (number lock) status, when the external keyboard is pressed, the method comprising:
when NL status of the computer is “Off” and NL status of the external keyboard is “On”, and a time internal between adjacent serially-pressed numeric keys of the external keyboard is less than a predetermined time period,
firstly sending a key code of NL on the external keyboard to alter NL status of the computer from “Off” to “On”, secondly sending key codes of pressed numeric keys of the external keyboard to the computer, and finally sending the key code of NL on the external keyboard to alter NL status of the computer from “On” to “Off”; and
when NL status of the computer is “On” and NL status of the external keyboard is “Off”, and a time internal between adjacent serially-pressed numeric keys of the external keyboard is less than the predetermined time period,
firstly sending the key code of NL on the external keyboard to alter NL status of the computer from “On” to “Off”, secondly sending key codes of pressed numeric keys of the external keyboard to the computer, and finally sending the key code of NL on the external keyboard to alter NL status of the computer from “Off” to “On”.

13. The method of claim 12, wherein the predetermined time period is 0.3˜0.5 sec.

14. The method of claim 13, further comprising:
when NL status of the computer is “Off” and NL status of the external keyboard is “Off”, sending key codes of pressed keys of the external keyboard to the computer.

15. The method of claim 14, further comprising:
when NL status of the computer is “On” and NL status of the external keyboard is “On”, sending key codes of pressed keys of the external keyboard to the computer.

16. The method of claim 12, further comprising:
when NL status of the computer is “Off” and NL status of the external keyboard is “Off”, sending key codes of pressed keys of the external keyboard to the computer.

17. The method of claim 12, further comprising:
when NL status of the computer is “On” and NL status of the external keyboard is “On”, sending key codes of pressed keys of the external keyboard to the computer.
